(19) United States
(12) Patent Application Publication
(10) Pub. No.: US 2006/0244647 A1
(43) Pub. Date: Nov. 2, 2006

(54) Digital-to-analog converter and successive approximation type analog-to-digital converter utilizing the same

(75) Inventor: Yoh Takano, Ogaki-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/411,931

(22) Filed: Apr. 27, 2006

(30) Foreign Application Priority Data
Apr. 27, 2005 (JP) 2005-130524

(51) Int. Cl. H03M 1/66

(52) U.S. Cl. 341/144

(57) ABSTRACT

In a digital-to-analog (D-A) converter, a plurality of respectively weighted capacitances are configured such that one ends of them are connected to an input terminal of a comparator and the other ends of them are connected to a power supply line or ground line. A plurality of switches selectively connect the other ends of corresponding capacitances with the power supply line or ground line. A possible range of capacitance division ratio in the plurality of capacitances is set in a manner that the magnitude and position of an output voltage range of the D-A converter is set to a desired value within a voltage range between power supply voltage and ground potential.

### BACKGROUND OF THE INVENTION

1. Field of the Invention

The present invention relates to an digital-to-analog converter that generates the desired analog signal by adjusting the division ratio in the capacitance division and a successive approximation type analog-to-digital converter utilizing the same.

2. Description of the Related Art

Digitization of many of electronic hardware, such as cameras, communication instruments and home electric appliances, is progressing. The natural world, however, is full of analog information for audio and video reproduction, and hence the conversion technology between analog signals and digital signals is rising in importance. There are a variety of types of analog-to-digital converters (hereinafter referred to as “A-D converters” as appropriate), and one of them is the successive approximation type A-D converter (See Reference (1) in the following Related Art List, for instance).

A successive approximation type A-D converters includes a successive approximation register (SAR), a digital-to-analog converter (hereinafter referred to as “D-A converters” as appropriate), and a comparator. The comparator compares an analog input voltage with an analog output voltage from the D-A converter.

Related Art List

(1) Jens Sauerbrey et al., “A 0.5V, 1 μW

Successive Approximation ADC”, ESSCIRC2002, pp. 247-250.

A comparator has an input voltage range. Therefore, the output voltage range of the above-mentioned D-A converter that supplies reference voltages to the above-mentioned comparator must be in correspondence to the input voltage range thereof. Thus it has conventionally been necessary to either adjust the level of at least one of the high-potential-side reference voltage and low-potential-side reference voltage to be supplied to the above-mentioned D-A converter or use a comparator corresponding to the output voltage range of the above-mentioned D-A converter.

If a supply voltage VDD is used as the above-mentioned high-potential-side reference voltage and a ground potential GND as the above-mentioned low-potential-side reference voltage, then the output voltage range of the above-mentioned D-A converter is basically from the supply voltage VDD to the ground potential. In this case, it is necessary to prepare a comparator having an input voltage range corresponding to this voltage range.

On the other hand, if it is attempted to achieve a correspondence between the two voltage ranges by adjusting the reference voltage to be supplied to a D-A converter, a problem may arise when a reference voltage intermediate under a low supply voltage condition at the D-A converter has passed the switch. That is, when a CMOS switch is used, the supply voltage is supplied into the circuit via PMOS and the ground potential is supplied into the circuit via NMOS. When the supply voltage is low, however, the use of a potential intermediate between the supply voltage and the ground potential may sometimes cause a slowed speed or an inaccurate conduction of the potential because it gets closer to the cut-off regions of PMOS and NMOS. In view of the increasing use of mixed mounting of analog circuits with digital circuits on the same substrate, therefore, it is all the more important to devise effective ways to respond to low supply voltage. There are, in fact, a number of proposals for a comparator system having a wider input voltage range, but they tend to rely on more complex circuits, which raise the costs. In contrast, it may contribute to an efficient designing of a successive approximation type A-D converter if there is a D-A converter which has a simple circuit structure, is operable under a low supply voltage condition, and allows the setting of a desired output voltage range.

### SUMMARY OF THE INVENTION

The present invention has been made in view of the foregoing circumstances and a general purpose thereof is to provide a D-A converter that allows the setting of a desired output voltage range irrespective of a given reference voltage level and a successive approximation type A-D converter using said D-A converter.

In order to solve the above problems, an digital-to-analog (D-A) converter according to one embodiment of the present invention is a D-A converter capable of generating the number of voltage levels corresponding to a resolution based on a high-potential-side reference voltage and a low-potential-side reference voltage, and the D-A converter comprises: a plurality of respectively weighted capacitances each one end of which connects to an output node and each other end of which connects to either the high-potential-side reference voltage or the low-potential-side reference voltage; and a switch which switches a connection in at least one of the plurality of capacitances between the high-potential-side reference voltage and the low-potential-side reference voltage. A possible range of capacitance division ratio in the plurality of capacitances is set in a manner that the magnitude and position of an output voltage range of the D-A converter is set to a predetermined target value within a voltage range between the high-potential-side reference voltage and the low-potential-side reference voltage. According to this embodiment, a desired output voltage range can be set irrespective of the level of the high-potential-side reference voltage and low-potential-side reference voltage.

The plurality of capacitances may include a plurality of capacitances for adjustment which adjust the magnitude of the output voltage range of the D-A converter and a plurality of capacitances with which to generate voltage width corresponding to each digit when converted to a digital signal with a predetermined resolution. According to this embodiment, the provision of adjusting capacitances allows the adjustment of the possible range of capacitance division ratio, so that a desired output voltage range can be set.

Another embodiment of the present invention relates also to a digital-to-analog (D-A) converter. This digital-to-analog converter is a D-A converter that utilizes a plurality of respectively weighted capacitances, and is such that a capacitance for generating a voltage width corresponding to each digit is provided in plurality. Since the number of possible capacitance division ratios can be increased, the area for the total capacitance can be made smaller.

Among a plurality of capacitances for generating voltage widths corresponding to the respective digits, an initial output voltage of the D-A converter may be generated by a capacitance division at an initial state in a manner such that part of capacitance is connected to a high-potential-side reference voltage and the other capacitance is connected to a low-potential-side reference voltage. According to this embodiment, the initial output voltage can be produced while there is no need to separately provide a capacitance for generating the voltage width corresponding to the initial output voltage.

The D-A converter may further include a capacitance for adjustment which adjusts the magnitude of an output voltage range of the D-A converter. According to this embodiment, a desired output voltage range can be set irrespective of the levels of the high-potential-side reference voltage and low-potential-side reference voltage. For example, the output voltage range can be squeezed between the high-potential-side reference voltage and the low-potential-side reference voltage.

There may be provided a plurality of the adjusting capacitances and, at an initial state, part of the adjusting capacitance may be connected to the high-potential-side reference voltage and the other adjusting capacitance may be connected to the low-potential-side reference voltage, and an initial output voltage of the D-A converter by a capacitance division may be set to a predetermined target value. A position of an output voltage range of the D-A converter may be adjusted in a manner that each capacitance value of the plurality of adjusting capacitances is adjusted as an independent variable. According to this embodiment, not only the magnitude of the output voltage range but also the position thereof can be adjusted, so that the output voltage range can be set more flexibly.

Still another embodiment of the present invention relates to a successive approximation type analog-to-digital (A-D) converter. This successive approximation type A-D converter utilizes an output voltage of the above-described D-A converter as a reference voltage. According to this embodiment, the voltage having the efficient range as a reference voltage of the successive approximation type A-D converter can be supplied from a D-A converter.

Still another embodiment of the present invention relates also to a successive approximation type A-D converter. This successive approximation type A-D converter comprises: an above-described D-A converter; a comparator which compares an output voltage from the D-A converter with an input analog signal; and a successive approximation register which varies a capacitance division ratio in response to an output result of the comparator. According to this embodiment, the comparator can receive the reference voltage whose range is suitable for the input voltage range and therefore the circuit as a whole can operate efficiently.

Arbitrary combinations of the aforementioned constituting elements, and the implementation of the present invention in the form of a method, an apparatus, a system and so forth may also be effective as and encompassed by the embodiments of the present invention.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 illustrates a structure of a D-A converter according to an embodiment of the present invention and a structure of a successive approximation type A-D converter including it.

FIG. 2 illustrates a structure of a D-A converter in the first comparative example and a structure of a successive approximation type A-D converter including it.

FIG. 3 illustrates a structure of a D-A converter in the second comparative example and a structure of a successive approximation type A-D converter including it.

### DETAILED DESCRIPTION OF THE INVENTION

The invention will now be described by reference to the preferred embodiments. This does not intend to limit the scope of the present invention, but to exemplify the invention.

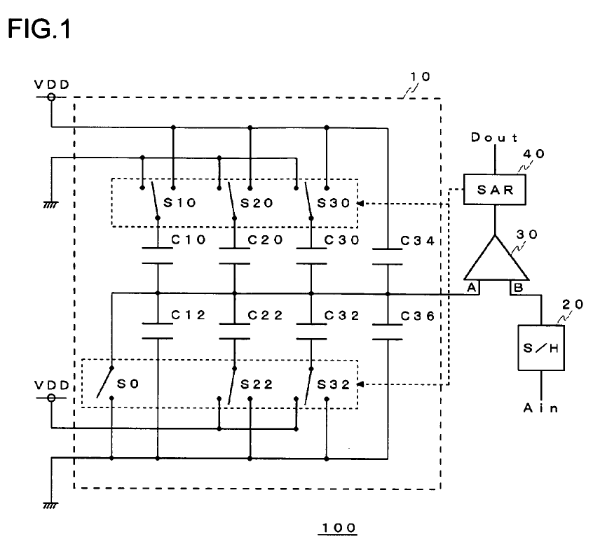

FIG. 1 illustrates a structure of a D-A converter 10 according to an embodiment of the present invention and a structure of a successive approximation type A-D converter 100 including the D-A converter 10. The successive approximation type A-D converter 100 includes a D-A converter 10, a sample-and-hold circuit 20, a comparator 30, and a successive approximation register (SAR) 40. The D-A converter 10 generates the number of voltage levels corresponding to its resolution, based on the two voltage levels of supply voltage VDD and ground potential GND. For example, for a resolution of 3 bits, at least seven voltage levels are generated. The D-A converter 10 supplies the generated voltage levels to a first input terminal A of the comparator 30. The detail of the D-A converter 10 will be described later.

The sample-and-hold circuit 20 samples an input analog signal Ain with predetermined timing and holds it for a predetermined period. For a successive approximation type A-D converter 100, which takes a certain time to carry out an A-D conversion, it is necessary to hold a sampled value to prevent the value of the analog input signal from changing during that time. The sample-and-hold circuit 20 supplies the voltage level of the held value to a second input terminal B of the comparator 30. It is to be noted here that a switched-capacitor type or the like may be used as a sample-and-hold circuit 20.

The comparator 30 compares a voltage supplied from the D-A converter 10 with a voltage supplied from the sample-and-hold circuit 20 and outputs a high-level signal or a low-level signal to the successive approximation register 40 according to the result of the comparison. For example, a high-level signal may be outputted when the voltage supplied from the sample-and-hold circuit 20 is higher than the voltage supplied from the D-A converter 10, and a low-level signal may be outputted when the former is lower than the latter.

The successive approximation register 40 controls a group of switches, to be described later, forming a D-A converter 10, according to the result of comparison by the comparator 30. The D-A converter 10 generates a new reference voltage according to this control and supplies it to the first input terminal A of the comparator 30. The comparator 30 again compares this voltage with a voltage supplied from the sample-and-hold circuit 20 and outputs the result of the comparison to the successive approximation register 40. And this processing is repeated to determine the value of each digit place. The successive approximation register 40 may be provided with a holding register that holds a digital value in its respective digit places and may output externally the contents of the holding register as a digital signal after conversion when the values for all the digits are determined. The signal may be outputted serially or parallelly depending on the type of wiring.

Now a detailed description is given of a structure of the D-A converter 10. The D-A converter 10 as shown in FIG. 1 converts digital signals to analog signals at a resolution of 3 bits. In the path leading to the first input terminal A of the comparator 30, a plurality of respectively weighted capacitances are connected in parallel.

A first capacitor C10 for adjustment (hereinafter referred to as “first adjusting capacitor C10” also) and a second capacitor C12 for adjustment (hereinafter referred to as “second adjusting capacitor C12” also) adjust the width and position of the output voltage range of the D-A converter 10. This adjustment method will be described in detail later. The first capacitor C10 for adjustment and the second capacitor C12 for adjustment are to have the same capacitance value unless otherwise indicated. One end of the first adjusting capacitor C10 and that of the second adjusting capacitor C12 are each connected to the path leading to the first input terminal A of the comparator 30. The other end of the first adjusting capacitor C10 is connected to one end of a switch S10 for adjustment (hereinafter referred to as “adjusting switch S10” also). The other end of the second adjusting capacitor C12 is connected to a ground line that supplies a low-potential-side reference potential.

The other end of the adjusting switch S10 is so configured as to be selectively connected to a power supply line supplying a high-potential-side reference potential or the above-mentioned ground line. According to the control from the successive approximation register 40, the adjusting switch S10 connects the first adjusting capacitor C10 to either the power supply line or the ground line.

An n−1 digit first capacitor C20 and an n−1 digit second capacitor C22 are capacitors for generating a voltage width for determining mainly the value of the bit next to the most significant bit. The n−1 digit first capacitor C20 and the n−1 digit second capacitor C20 have the same capacitance value, which is ½ of the capacitance value of the first adjusting capacitor C10 and the second adjusting capacitor C12. One end of the n−1 digit first capacitor C20 and that of the n−1 digit second capacitor C22 are each connected to the path leading to the first input terminal A of the comparator 30. The other ends thereof are connected respectively to one end of an n−1 digit first switch S20 and that of an n−1 digit second switch S22.

The other end of the n−1 digit first switch S20 and that of the n−1 digit second switch S22 are so configured as to be selectively connected to the above-mentioned power supply line or the above-mentioned ground line. According to the control from the successive approximation register 40, the n−1 digit first switch S20 and the n−1 digit second switch S22 connect the n−1 digit first capacitor C20 and the n−1 digit second capacitor C22, respectively, to either the power supply line or the ground line.

An n−2 digit first capacitor C30, an n−2 digit second capacitor C32, an n−2 digit third capacitor C34, and an n−2 digit fourth capacitor C36 are capacitors for generating a voltage width for determining mainly the value of the bit which is two bit positions below the most significant bit. In FIG. 1, they are the capacitors to generate a voltage width for determining the value of the least significant bit. The n−2 digit first capacitor C30, the n−2 digit second capacitor C32, the n−2 digit third capacitor C34, and the n-2 digit fourth capacitor C36 have the same capacitance value, which is ¼ of the capacitance value of the first adjusting capacitor C10 and the second adjusting capacitor C12. The one ends of the n−2 digit first capacitor C30, the n−2 digit second capacitor C32, the n−2 digit third capacitor C34, and the n−2 digit fourth capacitor C36 are connected to the path leading to the first input terminal A of the comparator 30. The other end of the n−2 digit third capacitor C34 is connected to the above-mentioned power supply line, whereas the other end of the n−2 digit fourth capacitor C36 is connected to the above-mentioned ground line.

The other ends of the n−2 digit first capacitor C30 and the n−2 digit second capacitor C32 are connected respectively to the one ends of an n−2 digit first switch S30 and an n−2 digit second switch S32. The other ends of the n−2 digit first switch S30 and the n−2 digit second switch S32 are so configured as to be selectively connected to the above-mentioned power supply line or the above-mentioned ground line. According to the control from the successive approximation register 40, the n−2 digit first switch S30 and the n−2 digit second switch S32 connect the n−2 digit first capacitor C30 and the n−2 digit second capacitor C32, respectively, to either the power supply line or the ground line.

Further, a resetting switch S0 is provided between the path leading to the first input terminal A of the comparator 30 and the above-mentioned ground line. The resetting switch S0, by turning on, can set the first input terminal A of the comparator 30 to the ground potential. It is turned on and off by the control from the successive approximation register 40 or the like.

Next, a description will be given of an operation of the successive approximation type analog-to-digital (A-D) converter 100. At an initial state, the D-A converter 10 is such that the resetting switch S0 is turned on and the adjusting switch S10, n−1 digit first switch S20, n−1 digit second switch S22, n−2 digit first switch S30 and n−2 digit second switch S32 are all connected to the ground line. As a result thereof, the capacitance of the D-A converter 10 as a whole is discharged to bring the potential at the first input terminal A of the comparator 30 to the ground potential.

Then, when an analog signal Ain is inputted to the successive approximation type A-D converter 100, the sample-and-hold circuit 20 samples the voltage of the analog signal Ain with predetermined timing and supplies it to a second input terminal B of the comparator 30. As the sampled voltage appears at the second input terminal B of the comparator 30, the resetting switch S0 is switched to OFF and the connection of the adjusting switch S10, n−1 digit first switch S20 and n−2 digit first switch S30 is all switched from the above-mentioned ground line to the above-mentioned power supply line. As a result, a series circuit is formed with the combined capacitance of the first adjusting capacitor C10, the n−1 digit first capacitor C20, the n−2 digit first capacitor C30 and the n−2 digit third capacitor C34 and the combined capacitance of the second adjusting capacitor C12, the n−1 digit second capacitor C22, n−2 digit second capacitor C32 and the n−2 digit fourth capacitor C36. It is assumed here that the capacitance value of each of pairs of capacitors is the same. Then, the capacitance is divided one to one, and the voltage of ½ of the supply voltage VDD is applied to the first input terminal A of the comparator 30.

Next, the comparator 30 compares the voltage supplied from the D-A converter 10, which is ½ of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to SAR 40 when the latter is lower than the former.

The successive approximation register 40 holds the output signal from the comparator 30 as a value of the most significant bit. When the output signal is a low-level signal, the successive approximation register 40 outputs a control signal to the n−1 digit second switch S22 to switch the connection from the above-mentioned ground line to the above-mentioned power supply line. Then, a series circuit is formed with the combined capacitance of the first adjusting capacitor C10, the n−1 digit first capacitor C20, the n−1 digit second capacitor C22, the n−2 digit first capacitor C30 and the n−2 digit third capacitor C34 and the combined capacitance of the second adjusting capacitor C12, the n−2 digit second capacitor C32 and the n−2 digit fourth capacitor C36. In this case, the capacitance is divided five to three, and the voltage of ⅜ of the supply voltage VDD is applied to the first input terminal A of the comparator 30.

When, on the other hand, the output signal from the comparator 30 is a high-level signal, the successive approximation register 40 outputs a control signal to the n-1 digit first switch S20 to switch the connection from the above-mentioned power supply line to the above-mentioned ground line. Then, a series circuit is formed with the combined capacitance of the first adjusting capacitor C10, the n−2 digit first capacitor C30, the n−2 digit third capacitor C34, and the combined capacitance of the second adjusting capacitor C12, the n−1 digit first capacitor C20, the n−1 digit second capacitor C22, the n−2 digit second capacitor C32 and the n−2 digit fourth capacitor C36. In this case, the capacitance is divided three to five, and the voltage of ⅝ of the supply voltage VDD is applied to the first input terminal A of the comparator 30.

Next, when the most significant bit is a low-level signal, the comparator 30 compares the voltage supplied from the D-A converter 10, which is ⅜ of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to SAR 40 when the latter is lower than the former.

The successive approximation register 40 holds the output signal from the comparator 30 as a value of a bit next to the most significant bit. When the output signal is a low-level signal, the successive approximation register 40 outputs a control signal to the n−2 digit second switch S32 to switch the connection from the above-mentioned ground line to the above-mentioned power supply line. Then, a series circuit is formed with the combined capacitance of the first adjusting capacitor C10, the n−1 digit first capacitor C20, the n−1 digit second capacitor C22, the n−2 digit first capacitor C30, the n−2 digit second capacitor C32 and the n−2 digit third capacitor C34 and the combined capacitance of the second adjusting capacitor C12 and the n-2 digit fourth capacitor C36. In this case, the capacitance is divided eleven to five, and the voltage of 5/16 of the supply voltage VDD is applied to the first input terminal A of the comparator 30.

When, on the other hand, the output signal from the comparator 30 is a high-level signal, the successive approximation register 40 outputs a control signal to the n-2 digit first switch S30 to switch the connection from the above-mentioned power supply line to the above-mentioned ground line. Then, a series circuit is formed with the combined capacitance of the first adjusting capacitor C10, the n−1 digit first capacitor C20, the n−1 digit second capacitor C22 and the n−2 digit third capacitor C34, and the combined capacitance of the second adjusting capacitor C12, the n−2 digit first capacitor C30, the n−2 digit second capacitor C32 and the n−2 digit fourth capacitor C36. In this case, the capacitance is divided nine to seven, and the voltage of 7/16 of the supply voltage VDD is applied to the first input terminal A of the comparator 30.

Next, when the most significant bit is a low-level signal and the next bit is also a low-level signal, the comparator 30 compares the voltage supplied from the D-A converter 10, which is 5/16 of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to SAR 40 when the latter is lower than the former.

When, on the other hand, the most significant bit is a low-level signal and the next bit is a high-level signal, the comparator 30 compares the voltage supplied from the D-A converter 10, which is 7/16 of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to SAR 40 when the latter is lower than the former.

Next, when the most significant bit is a high-level signal in the processing of a bit next to the most significant bit, the comparator 30 compares the voltage supplied from the D-A converter 10, which is ⅝ of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to SAR 40 when the latter is lower than the former.

The successive approximation register 40 holds the output signal from the comparator 30 as a value of the bit next to the most significant bit. When the output signal is a low-level signal, the successive approximation register 40 outputs a control signal to the n−2 digit second switch S32 to switch the connection from the above-mentioned ground line to the above-mentioned power supply line. In this case, the capacitance is divided seven to nine, and the voltage of 9/16 of the supply voltage VDD is applied to the first input terminal A of the comparator 30.

When, on the other hand, the output signal is a high-level signal, the successive approximation register 40 outputs a control signal to the n−2 digit first switch S30 to switch the connection from the above-mentioned power supply line to the above-mentioned ground line. In this case, the capacitance is divided five to eleven, and the voltage of 11/16 of the supply voltage VDD is applied to the first input terminal A of the comparator 30.

Now, when the most significant bit is a high-level signal and the next bit is a low-level signal, the comparator 30 compares the voltage supplied from the D-A converter 10, which is 9/16 of the supply voltage VDD, with the voltage supplied from the sample-and-hold circuit 20.

The comparator 30 outputs a high-level signal to the SAR 40 when the latter voltage is higher than or equal to the former or the comparator 30 outputs a low-level signal to SAR 40 when the latter is lower than the former.

When, on the other hand, the most significant bit is a high-level signal and the next bit is a high-level signal, the comparator 30 compares the voltage supplied from the D-A converter 10, which is 11/16 of the supply voltage VDD, with the voltage supplied from the sample-and-hold circuit 20.

The comparator 30 outputs a high-level signal to the SAR 40 when the latter voltage is higher than or equal to the former or the comparator 30 outputs a low-level signal to SAR 40 when the latter is lower than the former. By carrying out the above processing, the analog signal Ain sampled by the sample-and-hold circuit 20 is converted to a digital signal Dout of 3 bits.

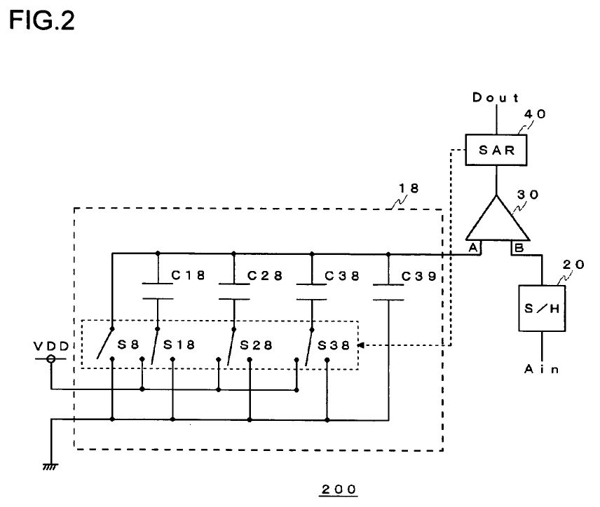

FIG. 2 illustrates a structure of a D-A converter 18 according to a first comparative example and a structure of a successive approximation type A-D converter 200 including the D-A converter 18. The structure of a successive approximation type A-D converter 200 according to the first comparative example is basically the same as that of the successive approximation type A-D converter 100 according to the embodiment shown in FIG. 1. The two differ from each other in the structure of the D-A converter 18 and the input voltage range of the comparator 30.

The D-A converter 18 as shown in FIG. 2 also converts digital signals to analog signals at a resolution of 3 bits. In the path leading to a first input terminal A of a comparator 30, a plurality of respectively weighted capacitors are connected in parallel.

An n digit capacitor C18 is a capacitor for generating a voltage width for determining mainly the value of the most significant bit. One end of the n digit capacitor C18 is connected to the path leading to the first input terminal A of the comparator 30, and the other end thereof to one end of an n digit switch S18. The other end of the n digit switch S18 is so configured as to be selectively connected to a power supply line supplying a high-potential-side reference potential or a ground line supplying a low-potential-side reference potential. According to the control from a successive approximation register 40, the n digit switch S18 connects the n digit capacitor C18 to either the power supply line or the ground line.

An n−1 digit capacitor C28 is a capacitor for generating a voltage width for determining mainly the value of the bit next to the most significant bit. The n−1 digit capacitor C28 has a capacitance value of ½ of that of the n digit capacitor C18. One end of the n−1 digit capacitor C28 is connected to the path leading to the first input terminal A of the comparator 30, and the other end thereof to one end of an n−1 digit switch S28. The other end of the n−1 digit switch S28 is so configured as to be selectively connected to the above-mentioned power supply line or the above-mentioned ground line. According to the control from the successive approximation register 40, the n−1 digit switch S28 connects the n−1 digit capacitor C28 to either the power supply line or the ground line.

An n−2 digit first capacitor C38 and an n−2 digit second capacitor C39 are capacitors for generating a voltage width for determining mainly the value of the bit which is two bit positions below the most significant bit. The n−2 digit first capacitor C38 and the n−2 digit second capacitor C39 have the same capacitance value, which is ¼ of the capacitance value of the n digit capacitor C18. The one ends of the n−2 digit first capacitor C38 and the n−2 digit second capacitor C39 are connected to the path leading to the first input terminal A of the comparator 30.

The other end of the n−2 digit first capacitor C38 is connected to an n−2 digit switch S38, whereas the other end of the n−2 digit second capacitor C39 is connected to the above-mentioned ground line. The other end of the n−2 digit switch S38 is so configured as to be selectively connected to the above-mentioned power supply line or the above-mentioned ground line. According to the control from the successive approximation register 40, the n−2 digit switch S38 connects the n−2 digit first capacitor C38 to either the power supply line or the ground line. Further, a resetting switch S8 is provided between the path leading to the first input terminal A of the comparator 30 and the above-mentioned ground line.

Now a description is given of an operation of the successive approximation type A-D converter 200 according to the first comparative example. In the initial state, the D-A converter 18 has all of the n digit switch S18, the n−1 digit switch S28 and the n−2 digit switch S38 connected to the ground line at the ON of the resetting switch S8. Accordingly, the capacitance of the D-A converter 18 as a whole is discharged to bring the potential at the first input terminal A of the comparator 30 to the ground potential.

Then, when an analog signal Ain is inputted to the successive approximation type A-D converter 200, the sample-and-hold circuit 20 samples the voltage of the analog signal Ain with predetermined timing and supplies it to a second input terminal B of the comparator 30. As the sampled voltage appears at the second input terminal B of the comparator 30, the resetting switch S8 is switched to OFF and the connection of the n digit switch S18 is switched from the above-mentioned ground line to the above-mentioned power supply line. As a result, a series circuit is formed with the combined capacitance of the n digit capacitor C18, the n−1 digit capacitor C28, the n−2 digit first capacitor C38 and the n−2 digit second capacitor C39. The capacitance is divided one to one, and a voltage of ½ of the supply voltage VDD is applied to the first input terminal A of the comparator 30.

Next, the comparator 30 compares the voltage supplied from the D-A converter 18, which is ½ of the supply voltage VDD, with the voltage supplied from the sample-and-hold circuit 20. The comparator 30 outputs a high-level signal to the SAR 40 when the latter voltage is higher than or equal to the former or the comparator 30 outputs a low-level signal to the SAR 40 when the latter is lower than the former.

The successive approximation register 40 holds the output signal from the comparator 30 as a value of the most significant bit. When the output signal is a low-level signal, the successive approximation register 40 outputs a control signal to the n−1 digit switch S28 to switch the connection from the above-mentioned ground line to the above-mentioned power supply line. In this case, the capacitance is divided three to one, and a voltage of ¼ of the supply voltage VDD is applied to the first input terminal A of the comparator 30. On the other hand, when the output signal from the comparator 30 is a high-level signal, the successive approximation register 40 outputs a control signal to the n digit switch S18 to switch the connection from the above-mentioned power supply line to the above-mentioned ground line and also outputs a control signal to the n−1 digit switch S28 to switch the connection from the above-mentioned ground line to the above-mentioned power supply line. In this case, the capacitance is divided one to three, and a voltage of ¾ of the supply voltage VDD is applied to the first input terminal A of the comparator 30.

From here on, on the same principle, the successive approximation register 40 can cause the D-A converter 18 to generate voltages of ⅛, ⅜, ⅝ and ⅞ of supply voltage VDD by controlling the n digit switch S18, the n−1 digit switch S28, the n−2 digit switch S30 according to the level of output signal from the comparator 30.

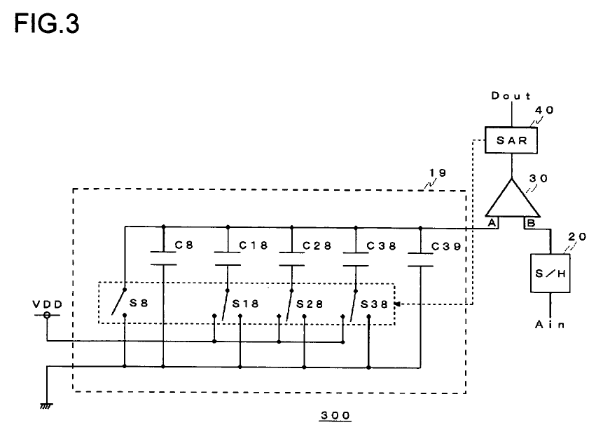

FIG. 3 illustrates a structure of a D-A converter 19 according to a second comparative example and a structure of a successive approximation type A-D converter 300 including the D-A converter 19. The structure of a successive approximation type A-D converter 300 according to the second comparative example is basically the same as that of a successive approximation type A-D converter 200 according to the first comparative example shown in FIG. 2. The two differ from each other in the structure of the D-A converter 19 and the input voltage range of the comparator 30.

The D-A converter 19 shown in FIG. 3 also converts digital signals to analog signals at a resolution of 3 bits. It differs from the D-A converter 18 of FIG. 2 in that an adjusting capacitor C8 is placed between the path leading to the first input terminal A of the comparator 30 and the above-mentioned ground line. The adjusting capacitor C8 has a capacitance value two times higher than that of the n digit capacitor C18.

Now a description is given of an operation of a successive approximation type A-D converter 300 according to the second comparative example. The operation of a successive approximation type A-D converter 300 according to the second comparative example is basically the same as that of the successive approximation type A-D converter 200 according to the first comparative example. Due to the introduction of an adjusting capacitor C8, however, it differs in the following respect. The output voltages that can be received by the D-A converter 18 in the first comparative example are voltages of ¼, ¾, ⅛, ⅜, ⅝ and ⅞ of the supply voltage VDD, with ½ thereof as the center. In contrast, the output voltages that can be received by the D-A converter 19 in the second comparative example are voltages of ⅛, ⅜, 1/16, 3/16, 5/16 and 7/16 of the supply voltage VDD, with ¼ thereof as the center.

Now, a description is given of the input voltage range of the comparator 30 according to the embodiment, the first comparative example and the second comparative example. The first input terminal A of the comparator 30 according to the embodiment receives the application of voltages in a range of 5/16 to 11/16 of the supply voltage VDD, with ½ thereof as the center, from the D-A converter 10. If the n−2 digit third capacitor C34 and the n−2 digit fourth capacitor C36 are so configured as to be connectable to the above-mentioned power supply line, the voltages in a range of ¼ to ¾ of the supply voltage VDD can be applied to the first terminal A of the comparator 30.

The first input terminal A of the comparator 30 according to the first comparative example receives the application of voltages in a range of ⅛ to ⅞ of the supply voltage VDD, with ½ thereof as the center, from the D-A converter 18. If the n−2 digit second capacitor C39 is so configured as to be connectable to the above-mentioned power supply line, the voltages in a range from supply voltage VDD to ground potential can be applied to the first terminal A of the comparator 30.

The first input terminal A of the comparator 30 according to the second comparative example receives the application of voltages in a range of 1/16 to 7/16 of the supply voltage VDD, with ¼ thereof as the center, from the D-A converter 19. If the n−2 digit second capacitor C39 is so configured as to be connectable to the above-mentioned power supply line, the voltages in a range from ½ of the supply voltage VDD to ground potential can be applied to the first terminal A of the comparator 30.

Compared with the first comparative example, the embodiment can provide ½ of the output voltage range of the D-A converter 10 and also ½ of the input voltage range of the comparator 30. This can lead to the simplification of the comparator design and cost reduction. This can also achieve the low supply voltage.

In contrast to the second comparative example, the embodiment can shift the output voltage range itself. That is, with the embodiment, the lower limit of the output voltage range is not the ground potential, and the output voltage range is positioned intermediate between supply voltage VDD and ground potential. As will be described later, the output voltage range can be set arbitrarily between the supply voltage VDD and the ground potential. Hence, the output voltage range can be easily adjusted in correspondence to the range of analog signal Ain inputted to the successive approximation type A-D converter 100.

Next, a description is given of a fact that a designer can shift the narrowed output voltage range to an arbitrary level. In the present embodiment, the total capacitance value TC of the D-A converter 10 is expressed by the following Equation (1).

Suppose that
C20=C22=C/2,
C30=C32=C34=C36=C/2,
C10=Ca and C12=Cb.

Then,

$$\begin{matrix}TC = Ca + Cb + 2 \times C / 2 + 4 \times C / 4 \\ = Ca + Cb + 2 C\end{matrix} \qquad Equation ( 1 )$$

In the present embodiment, the output voltage range VW is determined by the ratio of the total capacitance value TC and the capacitance value where the capacitance value Ca of the first adjusting capacitor C10 and the capacitance value Cb of the second adjusting capacitor C12 are removed from the total capacitance value TC, and therefore VW is expressed by the following Equation (2).
VW={2C/(Ca++Cb+2C)})×VDD Equation (2)

In the present embodiment, the voltage Aini which is to be applied to the first input terminal A of the comparator 30 is expressed, to determine the most significant bit, by the following Equation (3).
Aini=(Ca+C)/(Ca+Cb+2C)×VDD Equation (3)

The center value of the above-mentioned output voltage range VW is set to the initial voltage Aini. The designer needs to set the above capacitance values Ca and Cb so that the both ends of the output voltage range VW do not lie outside the range of between the supply voltage VDD and the ground potential.

So far, the description has been given of a case where the D-A converter 10 is of 3 bits. Hereinbelow, a description will be given of the fact that the present invention can be easily extended to the other bit numbers. That is, it is only necessary to adjust the number of capacitance groups which store the charge corresponding to 2C in the Equation (2). As described above, in the case of conversion by 3 bits, six capacitors are used where there are provided two capacitors of a given capacitance value and there are provided four capacitors whose capacitance value is ½ of the given capacitance value. In this regard, in the case of conversion by 4 bits, it is preferred that eight capacitors are used where there are provided two capacitors of a given capacitance value, there are provided two capacitors whose capacitance value is ½ of the given capacitance value and there are provided four capacitors whose capacitance value is ¼ of the given capacitance value. Then a predetermined number of capacitances are connected to the power supply line by a switch or switches and the remaining capacitances are connected to the ground line by the switch or switches, so that fifteen different values of voltages can be produced.

According to the present embodiments as described above, the output voltage range of the D-A converter can be set different from the voltage range between the supply voltage and the ground potential. For example, the output voltage range of the D-A converter can be set narrower than the voltage range between the supply voltage and the ground potential. Furthermore, the center value of the output voltage range can be set to an arbitrary level. Thus, the width and position of the output voltage range can be set arbitrarily without being constrained by the supply voltage level. As a result, when it is used as a reference voltage in the comparator, the reference voltage having an optimal range according to the input voltage range of the comparator and the voltage, for comparison, which is inputted to the comparator can be supplied. In addition, the area of the total capacitance will not increase. Also, no circuitry to boost or step down the voltage will be needed. When the D-A converter according to the present embodiment is made into an integrated structure and the switches are composed of transistors, the transistors need only to switch between the supply voltage and the ground potential, so that the switching control can be done in a large domain of margin in which the operation is guaranteed to work correctly.

The present invention has been described based on some embodiments. It is understood by those skilled in the art that these embodiments are merely exemplary, various modifications to the combination of each component and process thereof are possible and such modifications are also within the scope of the present invention.

A structure such that both the first adjusting capacitor C10 and the second adjusting capacitor C12 are not provided in the present embodiments is also within the scope of the present invention. In such a case, the output voltage range corresponding to the first comparative example can be realized with the smaller area of the total capacitance. More specifically, according to this modification the area can be made practically ½ of the area of the first comparative example. This is because two capacitances are provided for generating the voltage width of each digit and one capacitance of the two is connected to the power supply line for each digit and the initial voltage is produced in the state where the other one of the two is connected to the ground line.

A structure such that the adjusting capacitor C8 is divided into a plurality of capacitances, for example, two capacitances and part of them is so configured as to be selectively connected to the power supply line or the ground line in the second comparative example is also within the scope of the present invention. In such a case, too, a circuit configuration realizing the above Equation (2) is provided, so that the same advantageous effects as the present embodiments can be obtained except for those concerning the area of the total capacitance.

Other circuitries equivalent to the present embodiments where the number of capacitances is increased to achieve the term of 2C in the above Equation (2) and thereby the capacitance value is reduced by this much are also within the scope of the present invention. A modification where a voltage different from the supply voltage VDD is applied to a certain capacitor and the capacitance value thereof is varied in response thereto and the like, that is, a circuitry according to a modification where the relational expression Q=CV is satisfied is also within the scope of the present invention.

While the preferred embodiments of the present invention have been described using specific terms, such description is for illustrative purposes only, and it is to be understood that changes and variations may be made without departing from the spirit or scope of the appended claims.

What is claimed is:

1. An digital-to-analog (D-A) converter for generating the number of voltage levels corresponding to a resolution, based on a high-potential-side reference voltage and a low-potential-side reference voltage, the D-A converter comprising:
a plurality of respectively weighted capacitances each one end of which connects to an output node and each other end of which connects to either the high-potential-side reference voltage or the low-potential-side reference voltage; and
a switch which switches a connection in at least one of the plurality of capacitances between the high-potential-side reference voltage and the low-potential-side reference voltage,
wherein a possible range of capacitance division ratio in the plurality of capacitances is set in a manner that the magnitude and position of an output voltage range of said D-A converter is set to a predetermined target value within a voltage range between the high-potential-side reference voltage and the low-potential-side reference voltage.

2. A D-A converter according to claim 1, wherein the plurality of capacitances include a plurality of capacitances for adjustment which adjust the magnitude of the output voltage range of said D-A converter and a plurality of capacitances with which to generate voltage width corresponding to each digit when converted to a digital signal with a predetermined resolution.

3. A digital-to-analog (D-A) converter using a plurality of respectively weighted capacitances, characterized in that a capacitance for generating a voltage width corresponding to each digit is provided in plurality.

4. A D-A converter according to claim 3, wherein among a plurality of capacitances for generating voltage widths corresponding to the respective digits, at an initial state, part of capacitance is connected to a high-potential-side reference voltage and the other capacitance is connected to a low-potential-side reference voltage, and an initial output voltage of said D-A converter by a capacitance division is generated.

5. A D-A converter according to claim 3, further including a capacitance for adjustment which adjusts the magnitude of an output voltage range of said D-A converter.

6. A D-A converter according to claim 4, further including a capacitance for adjustment which adjusts the magnitude of an output voltage range of said D-A converter.

7. A D-A converter according to claim 5, wherein there are provided a plurality of the adjusting capacitances and, at an initial state, part of the adjusting capacitance is connected to the high-potential-side reference voltage and the other adjusting capacitance is connected to the low-potential-side reference voltage, and an initial output voltage of said D-A converter by a capacitance division is set to a predetermined target value.

8. A D-A converter according to claim 6, wherein there are provided a plurality of the adjusting capacitances and, at an initial state, part of the adjusting capacitance is connected to the high-potential-side reference voltage and the other adjusting capacitance is connected to the low-potential-side reference voltage, and an initial output voltage of said D-A converter by a capacitance division is set to a predetermined target value.

9. A D-A converter according to claim 2, wherein a position of an output voltage range of said D-A converter is adjusted in a manner that each capacitance value of the plurality of adjusting capacitances is adjusted as an independent variable.

10. A D-A converter according to claim 7, wherein a position of an output voltage range of said D-A converter is adjusted in a manner that each capacitance value of the plurality of adjusting capacitances is adjusted as an independent variable.

11. A D-A converter according to claim 8, wherein a position of an output voltage range of said D-A converter is adjusted in a manner that each capacitance value of the plurality of adjusting capacitances is adjusted as an independent variable.

12. A successive approximation type analog-to-digital converter characterized in that an output voltage of a digital-to-analog converter according to claim 1 is used as a reference voltage.
